(19) United States
(12) Patent Application Publication
(10) Pub. No.: US 2018/0204161 A1
(43) Pub. Date: Jul. 19, 2018

(54) WORKSITE ENERGY MANAGEMENT SYSTEM AND METHOD

(71) Applicant: Caterpillar Inc., Peoria, IL (US)

(72) Inventors: Mihai Sandulescu, Saint Charles, IL (US); Amit Kashyap, Elgin, IL (US); Gary Joseph Schueller, Dunlap, IL (US)

(73) Assignee: Caterpillar Inc., Peoria, IL (US)

(21) Appl. No.: 15/405,447

(22) Filed: Jan. 13, 2017

(51) Int. Cl. G06Q 10/06; G05D 1/00; G05D 1/02; G01R 21/133; G01R 31/36

(52) U.S. Cl. CPC G06Q 10/06315; G05D 1/0088; G01R 31/3606; G01R 21/133; G05D 1/021

(57) ABSTRACT

A worksite energy management system is providing having one or more energy storage devices, a charging station for charging the energy storage devices, one or more automated delivery machines configured to transport the one or more energy storage devices, and a worksite controller. Each automated delivery machine has a control module, where the worksite controller is in communication with each control module. The worksite controller configured to determine an energy demand and location of one or more work machines on a worksite, generate a travel path for the one or more automated delivery machines between a first location and a second location, and selectively communicate the travel path to each of the control modules.

### TECHNICAL FIELD

The present disclosure relates generally to a worksite energy management system and method, and more particularly to a worksite energy management system and method having one or more energy storage devices and one or more automated delivery machines.

### BACKGROUND

Construction, mining, waste management, manufacturing, and assembly worksites employ a variety of work machines and equipment that require power to operate. Common work machines include, for example, excavators, loaders, dozers, motor graders, haul trucks, and other types of heavy equipment used to perform tasks. Worksite equipment includes work machine support equipment, lighting, conveyors, and other equipment assisting worksite task performance. Many of these utilize electrical energy that can be powered using removable and interchangeable energy storage devices, including batteries and capacitors. Hybrid and fully electric work machines in particular may employ one or more energy storage devices powering the work machine and/or its accessories.

Emissions and energy dependence are ongoing problems at any worksite, including mines, quarries, and suburban work sites. Current technologies used to perform work and maintain a worksite use significant resources and emit emissions into the atmosphere. Future work machines and worksite systems may employ hybrid and fully electric machines, and future worksites may leverage renewable energy power sources in order to be self-sustaining. However, managing the power demands of each work machine in the worksite and of the worksite generally, while controlling the energy generated by a renewable energy power source, requires a comprehensive energy management system and method.

One energy management system and method is described in U.S. Patent Publication No. 2016/0247106 (the '106 publication) to Dalloro et al., published on Aug. 8, 2016. The '106 publication describes a computer-implemented method for managing a fleet of electric vehicles in order to optimize the use of such vehicles for transportation and energy storage purposes. The electric vehicles of the '106 publication are autonomous and selectively guided to parking lots to be charged. The battery packs of the vehicles provide energy storage for an electric grid while not being used for transportation purposes.

Although the system of the '106 publication may solve a particular need, it does not provide a worksite energy management system and method that can address the needs particular to a worksite and work machines. In particular, the '106 publication does not provide a plurality of interchangeable energy storage devices, a renewable energy power source, a plurality of work machines, and one or more automated delivery machines.

The disclosed system and method is directed to overcoming the one or more problems set forth above.

### SUMMARY OF THE INVENTION

In one aspect, the present disclosure is directed to a worksite energy management system including one or more energy storage devices, a charging station for charging the energy storage devices, one or more automated delivery machines configured to transport the one or more energy storage devices, and a worksite controller in communication with a control module on each automated delivery machine. The worksite controller is configured to determine an energy demand and a location of one or more work machines on a worksite, generate a travel path for the one or more automated delivery machines between a first location and a second location, and selectively communicate the travel path to each of the control modules.

In another aspect, the present disclosure is directed to a method of managing energy demands on a worksite, including monitoring a charge status of one or more energy storage devices, determining an energy demand and a location of one or more work machines on a worksite, generating a travel path for one or more automated delivery machines to transport one or more of the energy storage devices between a first location and a second location, and communicating the travel path to the one or more automated delivery machines.

### BRIEF DESCRIPTION OF THE DRAWINGS

FIG. 1 is an illustration of an exemplary disclosed worksite;

FIG. 2 is an illustration of an exemplary disclosed system that may be used to manage work machines and automated delivery machines at the worksite of FIG. 1;

FIG. 3 is an illustration of an worksite energy management system of the worksite of FIG. 1;

FIG. 4 is a system diagram of the worksite energy management system of the worksite of FIG. 1; and

FIG. 5 is an exemplary flowchart for operating the worksite energy management system of FIG. 3.

### DETAILED DESCRIPTION

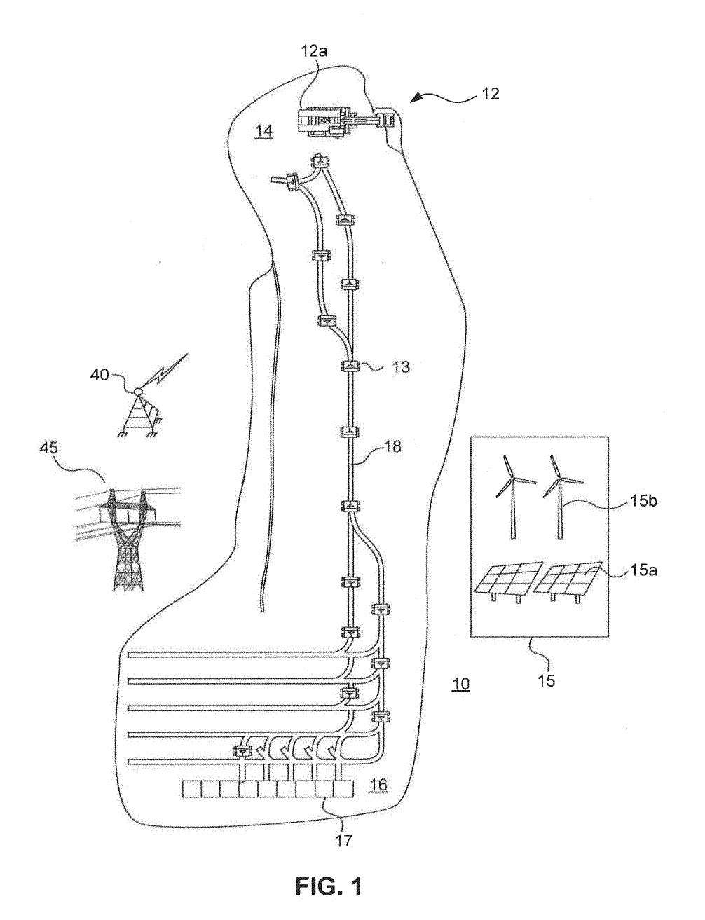

FIG. 1 illustrates an exemplary worksite 10 having one or more simultaneously-operable work machines 12 performing a variety of predetermined tasks. The worksite 10 may include, for example, a mine site, a landfill, a quarry, a construction site, or any other type of worksite known in the art. The predetermined tasks may be associated with altering the current geography at worksite 10 and include various assignments, including clearing operations, leveling operations, hauling operations, digging operations, loading operations, dumping operations, or any other type of work machine operation.

The worksite 10 may include multiple locations designated for particular purposes. For example, a first location 14 may be designated as a work location, at which a work machine 12 such as a mobile loading machine 12a or other resource operates to fill other haul machines with material. Support machines, such as automated delivery machines 13, may supply the work machines 12 with energy storage devices for powering the work machines 12 and/or their accessories. A second location 16 may be designated at the worksite 10 as a charging station 17, at which the automated delivery machines 13 pick up and deliver the energy storage devices for the energy storage devices to be charged. One or more travel paths 18 may generally extend between the first location 14 and the second location 16, and one or more automated delivery machines 13 may be simultaneously active on the worksite 10.

Any number and different types of work machines 12 may simultaneously and cooperatively operate at the worksite 10. For example, a loading machine 12a (e.g., an excavator shown in FIG. 1) may be stationed at the first location 14 and assigned to fill another work machine (e.g., a haul truck, etc.) with material. Other work machines 12 (e.g., dozers, motor graders, water trucks, and/or service vehicles) may be tasked with traveling up and down the worksite 10 to condition the travel paths 18, to clean up the work location, and/or to service other work machines 12 at any location of worksite 10.

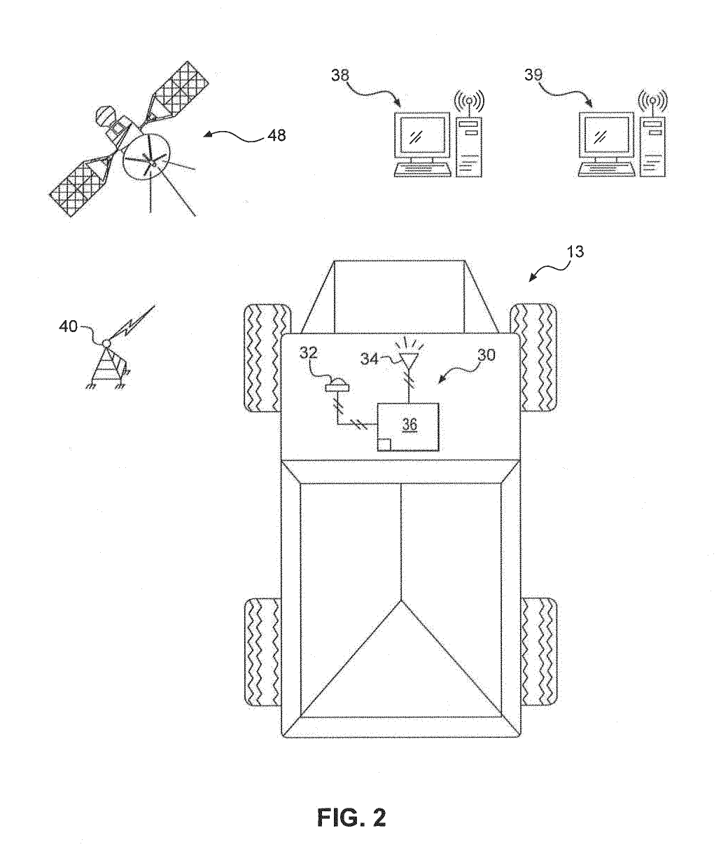

The work machines 12 may be self-directed machines configured to autonomously traverse the changing terrain of the worksite 10. Alternatively the work machines 12 may be manned machines configured to traverse worksite 10 under the control of a local or remote operator. The work machines 12 may also be semi-autonomous machines configured to perform some functions autonomously and other functions under the control of an operator. In an exemplary embodiment, the automated delivery machines 13 are fully autonomous or semi-autonomous, receiving direction from a worksite controller 38 (FIG. 2).

The automated delivery machines 13 may follow a travel path 18 that generally extends between the first and second locations 14, 16. The travel path 18 may be a predefined, static path and include structures or sensors for the automated delivery machines 13 to sense and follow. The travel path 18 may alternatively be an ad hoc pathway that can be configured based on demand. In the latter case, the travel path 18 is created by the worksite controller 38 and may be unique for each automated delivery machine 13. The travel path 18 may further be continuously updated as required while an automated delivery machine 13 is en route.

Factors that may cause an update to a pathway 18 may include the conditions of the worksite, needs of the work machines 12, and the location of the automated delivery machines 13. Using an ad hoc approach for guiding each automated delivery machine 13 allows the pathway 18 to account for changing shapes, dimensions, and general positions of the worksite 10 as conditions change over time, and allows for greater flexibility with respect to dispatching automated delivery machines 13 based on changing needs. In the disclosed embodiment, the automated delivery machines 13 are autonomously controlled and the pathway 18 is one of either a predefined pathway or one capable of continuous update.

As shown in FIG. 2, each automated delivery machine 13 may be equipped with a control module 30 that facilitates or enhances autonomous control. The control module 30 may include, among other things, a locating device 32, a communicating device 34, and an onboard controller 36 connected to the locating device 32 and the communicating device 34. The locating device 32 may be configured to determine a position of the automated delivery machine 13 in the worksite 10 and to generate a signal indicative thereof. The locating device 32 may embody, for example, a Global Positioning System (GPS) device, an Inertial Reference Unit (IRU), a local tracking system, or any other known locating device that receives or determines positional information associated with the automated delivery machine 13. The locating device 32 may be configured to convey a signal indicative of the received or determined positional information to the onboard controller 36 for processing. It is contemplated that the location signal may also be directed to one or more offboard interface devices (e.g., to a monitor) for display of each automated delivery machine 13 on an electronic representation of the worksite 10.

Communicating device 34 may include hardware and/or software that enables sending and receiving of data messages over a wireless communication link 40. The wireless communication link 40 may include a Global Navigation Satellite System (GNSS) 48, cellular network, or other alternative data link that enables data to be wireless transmitted from the onboard controller 36 to a worksite controller 38 over a network. The locating device 32 on each automated delivery machine 13 is configured to monitor movements of the particular automated delivery machine 13 and to generate corresponding location signals. The location signals may be directed to the onboard controller 36 and/or worksite controller 38 for comparison with an electronic map of the worksite 10 and for further processing. The further processing may include, among other things, determining a current location of each automated delivery machine 13; determining a distance between automated delivery machine 13 and other work machines 12; determining boundaries of travel paths 18; determining a speed of the automated delivery machine 13; and/or determining projected or assigned travel paths 18 of the automated delivery machine 13. This applies equally to automated delivery machines 13 traveling along predefined travel paths 18 or along ad hoc travel paths 18.

The communicating device 34 may facilitate communication between the onboard controllers 36 and/or between onboard controllers 36 and worksite controller 38. This communication may include, for example, the coordinates, speeds, and/or travel paths 18 of the automated delivery machine 13 generated based on signals from locating device 32. The communication may also include notification of travel path boundaries and/or identification of particular travel paths that have been authorized for use by certain automated delivery machine 13. Data messages may be sent and received via the wireless communication link 40. The wireless communications may include satellite, cellular, infrared, and any other type of wireless communications that enable communicating device 34 to exchange information between the worksite controller 38 and the onboard controller 36 of each automated delivery machine 13.

The data messages associated with control module 30 may also be sent and received via a direct data link, as desired. The direct data link may include an Ethernet connection, a connected area network (CAN), or another data link known in the art. The wireless communication link 40 may include satellite, cellular, infrared, and any other type of wireless communications that enable communicating device 34 to exchange information between worksite controller 38 and the components of control module 30.

The onboard controller 36 may embody a single or multiple microprocessors, field programmable gate arrays (FPGAs), digital signal processors (DSPs), etc., that include a means for controlling operations of automated delivery machine 13 in response to the needs of the worksite 10 and work machines 12, built-in constraints, sensed operational parameters, and/or communicated instructions from the worksite controller 38. Numerous commercially available microprocessors can be configured to perform the functions of these components. Various known circuits may be associated with these components, including power supply circuitry, signal-conditioning circuitry, actuator driver circuitry (i.e., circuitry powering solenoids, motors, or piezo actuators), and communication circuitry.

The worksite controller 38 may include any suitable means for monitoring, recording, storing, indexing, processing, and/or communicating various operational aspects of the worksite 10 and the automated delivery machines 13. These means may include components such as, for example, a memory, one or more data storage devices, a central processing unit, or any other components that may be used to run an application. Furthermore, although aspects of the present disclosure may be described generally as being stored in memory, one skilled in the art will appreciate that these aspects can be stored on or read from different types of computer program products or computer-readable media such as computer chips and secondary storage devices, including hard disks, floppy disks, optical media. CD-ROM, or other forms of RAM or ROM.

The worksite controller 38 may be configured to execute instructions stored on computer readable medium to perform methods of travel path planning and control for the automated delivery machines 13 at the worksite 10. In particular, the worksite controller 38 may direct the automated delivery machine 13 along a predefined or ad hoc travel path 18 between a first location 14 and a second location 16. The travel path 18 may be predefined and include sensors or structure to guide the automated delivery machines 13. Alternatively, the travel path 18 may be adaptable and unique for each automated delivery machine 13 based on needs at the worksite 10. The former type of pathway uses a static pathway, while the latter allows the automated delivery machine 13 to reach new locations and adapt to changing geography and terrain.

The worksite controller 38 may also execute the instructions to perform a method of planning that generates assignments for each automated delivery machine 13. These assignments include new travel paths 18, tasks including receiving or delivering energy storage devices to different locations on the worksite 10, and other control aspects for the automated delivery machines 13. These are communicated to the control modules 30 of the automated delivery machines 13 for implementation. As will be explained in more detail below, the worksite controller 38 may then manage movement of each automated delivery machine 13 along a travel path 18 to a particular target location.

In particular, the worksite controller 38 can transmit instructions to the onboard controller 36 of each automated delivery machine 13 and alter the current assignment of the machine. This may include communicating a new travel path, directing the automated delivery machines 13 to deliver or pick up one or more energy storage devices, to enter an idle support mode, or to update various parameters regarding the operation of the automated delivery machines 13.

By directing the movement of the automated delivery machine 13, the worksite controller 38 controls the movement and location of the energy storage devices at the worksite 10. The energy storage devices, including batteries, capacitors, and/or another form of energy storage device known in the art, are used primarily to provide power to the work machines 12. The energy storage devices are charged at the charging station 17 and delivered to the work machines 12 using the automated delivery machines 13. The worksite controller 38 creates the travel paths 18 and controls delivery and pick up of the energy storage devices, and thus tracks the location of each energy storage device at the worksite 10. In addition, the worksite controller 38 may track the charge status of each of the energy storage devices.

In addition to providing a worksite 10 with automated delivery machines 13, work machines 12, and a worksite controller 38, the present embodiment of the worksite 10 additionally includes a renewable energy power source 15. As show in FIG. 1, the renewable energy power source 15 is a local or remote power source that generates electrical power for the worksite 10. The renewable energy power source 15 may be utilized to supply power directly to the worksite 10 itself and/or charge the energy storage devices via the charging station 17. The renewable energy power source 15 may comprise one or more forms of energy generation utilizing a renewable source, including wind energy via wind mills 15b, solar energy via photovoltaic cells 15a (e.g., solar panels), hydroelectric energy via a dam or mill, geothermal energy, or any other power source deriving energy from a renewable source.

The worksite controller 38 may be configured, along with tracking the work machines 12 and automated delivery machines 13, to monitor the power demands of the worksite and the energy generated by the renewable energy power source 15. Using this information, along with the charge status of the energy storage devices on the worksite 10, the worksite controller 38 can determine how best to utilize the power being generated by the renewable energy power source 15. Several different options are available based on an energy demand of the worksite 10, the power being generated from the renewable energy power source 15, and the charge status of the energy storage devices. Power can be directed based on need and is determined by the worksite controller 38.

In one example, when the renewable energy power source 15 is generating electrical power and there is a need for electrical energy at the worksite 10, power from the renewable energy power source 15 may be used to power the worksite 10 directly. This may occur simultaneously with powering the charging station 17. The charging station 17 charges the energy storage devices at the worksite 10, which are used to power the work machines 12, other support equipment, and in some embodiments the automated delivery machines 13 themselves.

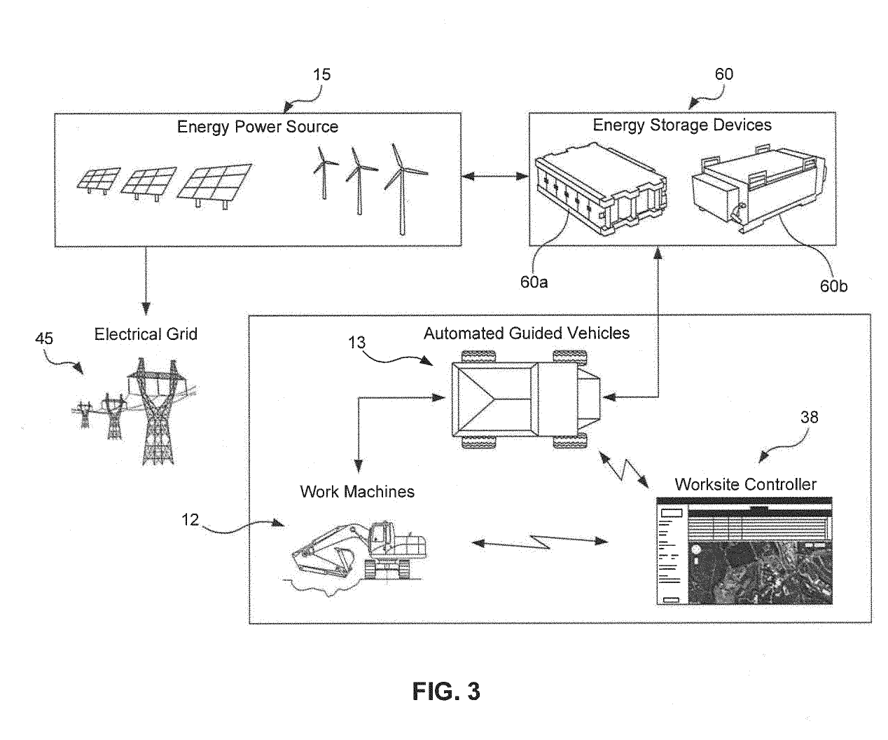

In another example, when energy demands from the worksite 10 are greater than the energy being created by the renewable energy power source 15, the energy storage devices may be used as a source of energy for the worksite 10. As shown in FIG. 3, the energy storage devices 60, including batteries 60a and/or capacitors 60b, store energy received from the renewable energy power source 15 when coupled to the charging station 17. Because renewable energy power sources by nature can fluctuate, the energy storage devices 60 can be used as reserve power for the worksite 10. During periods when the renewable energy power source 15 is producing less power than necessary to meet worksite demand, the energy storage devices 60 may be used to power the worksite 10. While coupled to the charging station 17 or otherwise connected to a worksite energy grid, the energy storage devices 60 may direct necessary power to the worksite 10 for continued operation. Examples of these occurrences may be when wind mills are not being powered by sufficient wind energy or when photovoltaic cells are operating during periods of low light.

In yet another example, when power demands at the worksite 10 are low and/or when the energy storage devices 60 are fully charged, the worksite controller 38 may be configured to direct power from the renewable energy power source 15 to an energy grid 45 external to the worksite 10 for use outside of the worksite 10. This may occur during periods of peak power generation and/or period of reduced power demand at the worksite 10.

Therefore, the worksite controller 38, as described above, is configured to determine how best to direct the power generated by the renewable energy power source 15 and how best to utilize the energy storage devices 60 at the worksite 10. The worksite controller 38 may therefore manage the power demands of the worksite 10, the power demands of each work machine 12 and automated delivery machine 13, and monitor the power generated by the renewable energy power source 15. In an embodiment, and as shown in FIG. 2, a secondary worksite controller 39 may also be utilized specifically for the energy management while a first worksite controller 38 may handle the operational aspects of the worksite 10. Therefore, the tasks of energy management and operations may be split between two or more controllers. In either embodiment, whether combined in one central worksite controller 38 or separated in two or more worksite controllers 38, 39, the worksite controllers may comprise one or more networked computing systems, providing necessary computing power to manage the operational aspects of the worksite and energy management requirements of the present system. In the disclosed embodiment, a single worksite controller 38, which may comprise one or more networked computing devices, handles both energy management and operations of the worksite 10.

The automated delivery machines 13 of the present disclosure are vehicles configured to traverse the worksite 10 and have suitable cargo capacity for carrying at least one energy storage device 60. In some embodiments, the automated delivery machines 13 may include wheeled vehicles. In other embodiments, the automated delivery machines 13 may include tracked vehicles. Further still, in other embodiments the automated delivery machines 13 may include airborne drones or unmanned aerial vehicles capable of flying at least one energy storage device 60 across the worksite 10. The automated delivery machines 13 may be fully electric or hybrid vehicles and may be powered by dedicated onboard energy storage device 60 and/or by one or more energy storage devices 60 carried by the automated delivery machine 13. For the dedicated energy storage device 60 powering the automated delivery machine 13, the dedicated energy storage device 60 may be charged by the charging station 17 and/or by onboard energy storage device 60 carried by the automated delivery machine 13.

### INDUSTRIAL APPLICABILITY

The disclosed worksite energy management system may be applicable to any worksite 10 that includes work machines 12. The disclosed worksite energy management system may provide a means for the worksite 10 to generate power locally or remotely to meet its own operational needs, therefore making the worksite 10 energy independent from an external energy grid. The disclosed worksite energy management system may also provide a means for the worksite 10 to operate its work machines 12 and support equipment using one or more energy storage devices 60, which reduces emitted pollution and reduces reliance on commodities such as diesel, gasoline, and natural gas. Finally, the disclosed worksite energy management system may provide a means for the worksite 10 direct energy back to an energy grid 45, therefore generating revenue for the worksite 10 and providing additional energy on the energy grid 45 for external use. The operation of disclosed worksite energy management will now be explained.

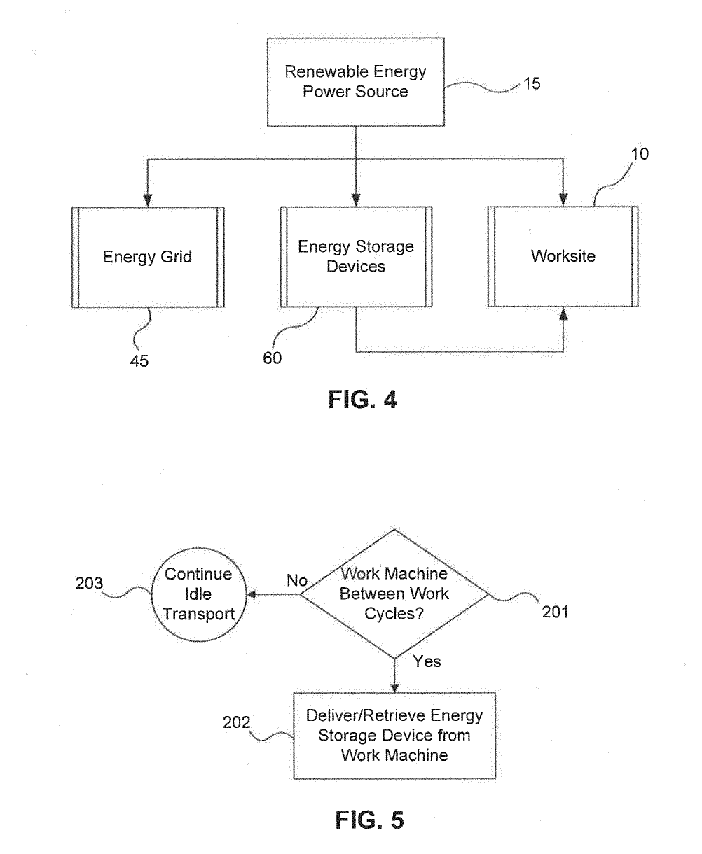

FIG. 4 shows a system diagram of the disclosed worksite energy management system. In particular, FIG. 4 illustrates the relationship between the renewable energy power source 15, the energy grid 45, the one or more energy storage devices 60, and the worksite 10. In the disclosed embodiment, the renewable energy power source 15 is a local or remote power source that supplies power to the worksite 10. The worksite controller 38 determines how to allocate the power generated by the renewable energy power source 15 between the worksite 10, the energy storage devices 60, and the energy grid 45. The renewable energy power source 15 may be used to power the worksite 10 and charge the energy storage devices 60, or at certain times the energy storage devices 60 may be used to power the worksite 10. Moreover, the renewable energy power source 15 may generate power away from the worksite 10 and back to the energy grid 45. The worksite controller 38 determines where to direct the supply of power based on need, and based on the power being generated by the renewable energy power source 15.

In one embodiment, the worksite controller 38 is configured to determine whether power is to be directed to the worksite 10 and/or the energy storage devices 60. Power to worksite 10 is used to power worksite systems and all other systems/equipment on the worksite 10 used to support operations. This may include all systems and equipment not including the charging station 17 that would traditionally be powered using grid power. The worksite controller 38 may be configured to determine the energy demands of the worksite 10, monitor power generated by the renewable energy power source 15, and direct power to the worksite 10 if the power generated by the renewable energy power source 15 exceeds the determined energy demand for the worksite 10.

As noted, the worksite controller 38 may consider the power demands of the charging station 17, and thus the power demands of the energy storage devices 60, separately from the power demands of the worksite 10. In this embodiment, the worksite controller 38 may be configured to monitor the charge status of each of the one or more energy storage devices 60 and the power demands of the work machines 12. Based on the charge status of each energy storage device 60 and the power demands of the work machines 12, the energy demand of the charging station 17 can be estimated and/or determined. The worksite controller 38 may then be configured to direct power to the charging station 17 (e.g., to the energy storage devices 60) if the demands of the worksite 10 are met and the energy storage devices 60 require recharging.

In determining where to direct power from the renewable energy power source 15, the worksite controller 38 may be configured to consider, collectively, the power demands of the worksite 10, the charge status of the energy storage devices 60, the power demands of the work machines 12, and the power being generated by the renewable energy power source 15. Both the charging station 17 (e.g., the energy storage devices 60) and the worksite 10 may simultaneously receive power from the renewable energy power source 15, or, alternatively, one may be powered at a time.

In yet another embodiment, the energy storage devices 60 may be used to power the worksite 10. During periods of low power generation by the renewable energy power source 15, when the supply of electrical power from the renewable energy power source 15 is less than required to power the worksite 10, power may be directed from the energy storage devices 60 to the worksite 10. In particular, the worksite controller 38 may be configured to determine an energy demand for the worksite 10 and use the energy storage devices 60 to direct power to the worksite 10 when power from the renewable energy power source 15 is unable to generate sufficient energy to power the worksite by itself.

The worksite controller 38 may also be configured to direct power back to the energy grid 45 in some embodiments. If the energy storage devices 60 are fully charged or charged above a threshold value and the worksite 10 does not require all of the power being generated from the renewable energy power source 15, the worksite controller 38 may be configured to direct power back to the energy grid 45. In some embodiments, the power may be simultaneously directed to the worksite 10, to the charging station 17 (e.g., to the energy storage devices 60), and back to the energy grid 45. This may occur during peak power generation periods when supply exceeds demand.

The worksite controller 38 may monitor the reserve energy storage of the energy storage devices 60. The reserve energy storage is the collective energy stored by the energy storage devices 60. If the reserve energy storage is below a threshold value, the worksite controller 38 may direct power to the charging station 17 to recharge the energy storage devices 60. If the reserve energy storage is above a threshold value and power being generated by the renewable energy power source 15 exceeds the needs of the worksite, the worksite controller 38 may direct power to the energy grid 45. Conversely, power may be directed to the worksite 10 from energy storage devices 60 if the energy demand for the worksite 10 exceeds the power generated by the renewable energy power source 15 and the reserve energy storage is above a threshold value.

The worksite controller 38 may also be configured to determine an energy demand for the work machines 12 on the worksite. Together with the location of the work machines 12, the worksite controller 38 generates a travel path 18 for one or more automated delivery machines 13 to transport one or more of the energy storage devices 60 to the work machines 12 determined an require additional energy. The worksite controller 38 communicates the travel path 18 to the one or more automated delivery machines 13 to deliver the energy storage devices 60 across the worksite 10. If no work machines 12 require additional energy (e.g., if their onboard energy supply is above a given threshold, for example), the energy storage devices 60 can be returned to the charging station 17 for charging, and powering the worksite 10 and/or directing power to the external energy grid 45.

The worksite controller 38 determines when and how to supply the energy storage devices 60 to each work machine 12 and when to retrieve them for recharging. In one embodiment, the worksite controller 38 may be configured to associate each of the energy storage devices 60 with one of the automated delivery machines 13, the charging station 17, or one of the work machines 12. Based on need and the location of each, the worksite controller 38 generates a new travel path 18 for those automated delivery machines 13 transporting energy storage devices 60 having a charge below a threshold value, the new travel path including returning to the charging station 17. Alternatively, the new travel path 18 may be to retrieve one or more of the energy storage devices 60 having a charge below a threshold value on a particular work machine 12, the new travel path 18 including traveling to the particular work machine 12 to retrieve one or more energy storage devices 60 and return to the charging station 17.

If one or more work machines 12 require additional power (e.g., they require replacement energy storage devices 60), the worksite controller 38 may be configured to generate a travel path for one or more automated delivery machines 13 to transport one or more of the energy storage devices 60 to the work machines 12. In one embodiment, and referring to FIG. 5, the worksite controller 38 may determine a work cycle of a particular work machine 12 (Step 201). Based on the work cycle (e.g., when the work machine is engaged in a task or between tasks), the worksite controller 38 may calculate an arrival time of a particular automated delivery machine 13 to arrive at the particular work machine 12 based on the work cycle of the particular work machine 12 and a travel time for the particular automated delivery machine 13. From this, the worksite controller 38 may generate a new travel path 18 for the particular automated delivery machine 13 to arrive at the particular work machine 12 at the arrival time (Step 202). This allows the arrival of the replacement energy storage devices to arrive at a time when the work machine 12 is able to stop work in order to exchange and/or take on the delivered energy storage devices. The worksite controller 38 selectively communicates the new travel path based on the work cycle to the control module of the particular automated delivery machine 13.

If the work cycle of the particular work machine 12 and/or its onboard energy storage devices 60 are sufficiently charged, immediate dispatch of the automated delivery machine 13 may not be desired. The worksite controller 38 may communicate an idle signal to the particular automated delivery machine 13 (Step 203). This may occur if the particular automated delivery machine 13 is already in the worksite 10 and away from the charging station 17, is carrying one or more energy storage devices 60, and will be needed in the near future for delivering the energy storage devices 60 to the particular work machine 12. Rather than returning to the charging station 17, the automated delivery machine 13 can enter an idle support mode 206 until such time it can deliver the energy storage devices 60 to the work machine 12 between work cycles.

Several advantages over the prior art may be associated with the worksite energy management system. One advantage may include facilitating energy independence of a worksite 10 by providing a renewable power source. Another advantage may include reducing pollution and emission from the worksite 10 and from work machines 12 by powering both using a renewable energy power source 15 and rechargeable energy storage devices 60. Finally, the worksite energy management system of the present disclosure may develop revenue for the worksite 10 by directing power back to an external energy grid 45.

It will be apparent to those skilled in the art that various modifications and variations can be made to the worksite energy management system. Other embodiments will be apparent to those skilled in the art from consideration of the specification and practice of the disclosed worksite energy management system. It is intended that the specification and examples be considered as exemplary only, with a true scope being indicated by the following claims and their equivalents.

What is claimed is:

1. A worksite energy management system, comprising:
one or more energy storage devices;
a charging station for charging the energy storage devices;
one or more automated delivery machines configured to transport the one or more energy storage devices, each automated delivery machine having a control module; and
a worksite controller in communication with each control module, the worksite controller configured to:
determine an energy demand and a location of one or more work machines on a worksite;
generate a travel path for the one or more automated delivery machines between a first location and a second location based on the determined energy demand and location of the one or more work machines; and
selectively communicate the travel path to each of the control modules.

2. The worksite energy management system of claim 1, wherein the worksite controller is further configured to:
determine an energy demand for the worksite; and
use the one or more energy storage devices to direct power to the worksite based on the determined energy demand.

3. The worksite energy management system of claim 1, wherein the worksite controller is further configured to:
monitor a charge status of each of the one or more energy storage devices;
associate each of the energy storage devices with one of the automated delivery machines, the charging station, or one of the work machines; and
generate a new travel path for those automated delivery machines transporting energy storage devices having a charge below a threshold value, the new travel path including returning to the charging station.

4. The worksite energy management system of claim 1, wherein the worksite controller is further configured to:
monitor a charge status of each of the one or more energy storage devices;
associate each of the energy storage devices with one of the automated delivery machines, the charging station, or one of the work machines; and
generate a new travel path for one of the automated delivery machines to retrieve one of the energy storage devices having a charge below a threshold value on a particular work machine, the new travel path including traveling to the particular work machine and returning to the charging station.

5. The worksite energy management system of claim 1, further including:
a renewable energy power source; and
wherein the worksite controller is further configured to:
monitor power generated by the renewable energy power source;
monitor a charge status of each of the one or more energy storage devices to determine an energy demand for the charging station;
determine an energy demand for the worksite; and
use the one or more energy storage devices to direct power to an energy grid if the power generated by the renewable energy power source exceeds the determined energy demand for the worksite and the determined energy demand for the charging station.

6. The worksite energy management system of claim 1, wherein the one or more energy storage devices further comprises one or more batteries.

7. The worksite energy management system of claim 1, wherein the one or more energy storage devices further comprises one or more capacitors.

8. The worksite energy management system of claim 1, wherein the worksite controller is further configured to:
determine a work cycle and a location of a particular work machine;
calculate an arrival time of a particular automated delivery machine to arrive at the location of the particular work machine based on the work cycle of the particular work machine and a travel time for the particular automated delivery machine;
generate a new travel path for the particular automated delivery machine to arrive at the particular work machine at the arrival time; and
selectively communicate the new travel path to the control module of the particular automated delivery machine.

9. The worksite energy management system of claim 1, wherein each of the one or more automated delivery machines further includes:
a communicating device and a location device, the communicating device being configured to communicate over a network to the worksite controller.

10. A worksite energy management system, comprising:
a worksite powered by a renewable energy power source;
one or more energy storage devices configured to be charged by a charging station that is powered by the renewable energy power source one or more automated delivery machines configured to transport the one or more energy storage devices to one or more work machines on the worksite; and
a worksite controller configured to:
monitor power generated by the renewable energy power source;
monitor a charge status of each of the one or more energy storage devices to determine a reserve energy storage;
determine an energy demand for the worksite; and
use the one or more energy storage devices to direct power to the worksite if the determined energy demand for the worksite exceeds the power generated by the renewable energy power source and the reserve energy storage is above a threshold value.

11. A method of managing energy demands on a worksite, comprising:
monitoring a charge status of one or more energy storage devices;
determining an energy demand and a location of one or more work machines on a worksite;
generating a travel path for one or more automated delivery machines to transport one or more of the energy storage devices between a first location and a second location based on the determined energy demand and location of the one or more work machines; and
communicating the travel path to the one or more automated delivery machines.

12. The method of claim 11, wherein generating a travel path further includes:
communicating an idle signal to one or more of the automated delivery machines.

13. The method of claim 11, further including:
determining an energy demand for the worksite; and
using the one or more energy storage devices to direct power to the worksite based on the determined energy demand.

14. The method of claim 11, further including:
associating each of the energy storage devices with one of the automated delivery machines, a charging station, or one of the work machines; and
generating a new travel path for those automated delivery machines transporting energy storage devices having a charge below a threshold value, the new travel path including returning to the charging station.

15. The method of claim 11, further including:
associating each of the energy storage devices with one of the automated delivery machines, a charging station, or one of the work machines; and
generating a new travel path for one of the automated delivery machines to retrieve one of the energy storage devices having a charge below a threshold value on a particular work machine, the new travel path including traveling to the particular work machine and returning to the charging station.

16. The method of claim 11, further including:
generating power using a renewable energy power source;
monitoring the power generated by the renewable energy power source;
determining an energy demand for a charging station based on the charge status of one or more energy storage devices;
determining an energy demand for the worksite; and
using the one or more energy storage devices to direct power to an energy grid if the power generated by the renewable energy power source exceeds the determined energy demand for the worksite and the determined energy demand for the charging station.

17. The method of claim 11, further including:
generating power using a renewable energy power source;
monitoring the power generated by the renewable energy power source;
determining a reserve energy storage based on the charge status of each of the one or more energy storage devices;
determining an energy demand for the worksite; and
using the one or more energy storage devices to direct power to the worksite if the determined energy demand for the worksite exceeds the power generated by the renewable energy power source and the reserve energy storage is above a threshold value.

18. The method of claim 11, further including:
determining a work cycle and a location of a particular work machine;
calculating an arrival time of a particular automated delivery machine to arrive at the location of the particular work machine based on the work cycle of the particular work machine and a travel time for the particular automated delivery machine;
generating a new travel path for the particular automated delivery machine to arrive at the particular work machine at the arrival time; and
selectively communicating the new travel path to the control module of the particular automated delivery machine.

19. The method of claim 11, wherein the one or more energy storage devices further comprises one or more batteries.

20. The method of claim 11, wherein the one or more energy storage devices further comprises one or more capacitors.
